(19) United States
(12) Patent Application Publication
(10) Pub. No.: US 2024/0151754 A1
(43) Pub. Date: May 9, 2024

(54) APPARATUS HAVING A SIX-PORT CIRCUIT AND METHOD FOR OPERATING SAME

(71) Applicants: Horst Siedle GmbH & Co. KG, Furtwangen (DE); Friedrich-Alexander-Universität Erlangen-Nürnberg, Erlangen (DE)

(72) Inventors: Ernst Halder, Stuttgart (DE); Fabian Lurz, Hamburg (DE); Gerold Sept-Enzel, Stuttgart (DE); Peter Dingler, Aalen-Ebnat (DE); Benedict Scheiner, Erlangen (DE)

(21) Appl. No.: 18/548,801

(22) PCT Filed: Feb. 22, 2022
(86) PCT No.: PCT/EP2022/054366

§ 371 Date: Sep. 1, 2023

(30) Foreign Application Priority Data
Mar. 2, 2021 (DE) 102021105006.5

(51) Int. Cl. G01R 23/02

(52) U.S. Cl. CPC G01R 23/02

(57) ABSTRACT

An apparatus comprising a six-port circuit, a delay device, and a computing device, wherein the delay device is adapted to divide an input signal into a first input signal and a second input signal, to delay the first input signal by a first delay time, wherein, for example, a first delayed input signal is obtained, to delay the second input signal by a second delay time, wherein, for example, a second delayed input signal is obtained, the second delay time being different from the first delay time, wherein the delay device is adapted to output the first delayed input signal to a first input of the six-port circuit, and to output the second delayed input signal to a second input of the six-port circuit, wherein the computing device is adapted to determine a first quantity characterizing a frequency of the input signal in dependence on at least one output signal of the six-port circuit.

### CROSS REFERENCE TO RELATED APPLICATIONS

The present application claims priority as a national stage application under 35 U.S.C. 371 to PCT Application No. PCT/EP2022/054366 filed on Feb. 22, 2022, entitled, “Apparatus Having a Six-Port Circuit, and Method for Operating Same,” which claims priority to DE Application No. 10 2021 105 006.5 filed on Mar. 2, 2021, both of which are incorporated by reference herein.

### FIELD

The disclosure relates to an apparatus comprising a six-port circuit and further relates to a method of operating an apparatus having a six-port circuit.

### BACKGROUND

The problems of the state of the art are resolved by a valve block body according to claim 1 and a device according to a separate claim.

### SUMMARY

Exemplary embodiments relate to an apparatus comprising a six-port circuit, a delay device, and a computing device, wherein the delay device is adapted to divide an input signal into a first input signal and a second input signal, to delay the first input signal by a first delay time, wherein, for example, a first delayed input signal is obtained, to delay the second input signal by a second delay time, wherein, for example, a second delayed input signal is obtained, the second delay time being different from the first delay time, wherein the delay device is adapted to output the first delayed input signal to a first input of the six-port circuit and to output the second delayed input signal to a second input of the six-port circuit, wherein the computing device is adapted to determine a first quantity characterizing a frequency of the input signal in dependence on at least one output signal of the six-port circuit.

In further exemplary embodiments, it is provided that the delay device comprises a first surface acoustic wave, SAW, delay line (e.g., based on a piezoelectric substrate) adapted, for example, to delay the first input signal by the first delay time, and/or a second surface acoustic wave, SAW, delay line (e.g., based on a piezoelectric substrate) adapted, for example, to delay the second input signal by the second delay time.

In further exemplary embodiments, it is provided that the delay device comprises a first conductor structure (e.g., arranged on a first circuit board) adapted, for example, to delay the first input signal by the first delay time, and/or that the delay device comprises a second conductor structure (e.g., arranged on an “own” second circuit board or, in further exemplary embodiments, together with the first conductor structure on the first circuit board) adapted, for example, to delay the second input signal by the second delay time.

In further exemplary embodiments, in which, for example, the first conductor structure and the second conductor structure are provided, a serial arrangement may be provided, for example, in which the first conductor structure and the second conductor structure are connected, for example, in series with one another, wherein, for example, the first conductor structure causes the first delay time, and wherein the second conductor structure, which by itself causes, for example, the second delay time as described, together with the first conductor structure causes an aggregated delay time which corresponds, for example, to a sum of the first delay time and the second delay time. In this respect, what is described further below for the second delay time (e.g., values for the delay time) applies accordingly to further exemplary embodiments with serial arrangement with respect to the aggregated delay time. For example, in further exemplary embodiments where, for example, the first conductor structure and the second conductor structure are provided, a parallel arrangement may be provided where the first conductor structure causes the first delay time and the second conductor structure causes the second delay time.

In further exemplary embodiments, it is provided that the delay device comprises a power splitting device adapted to split the input signal into the first input signal and the second input signal.

In further exemplary embodiments, it is provided that the first SAW delay line and/or the second SAW delay line are each implemented as a discrete SAW delay line.

In further exemplary embodiments, it is provided that the power splitting device is implemented as a discrete component.

In further exemplary embodiments, it is provided that the delay device comprises a circuit board, wherein at least one of the following elements is arranged on the circuit board: a) the first SAW delay line, b) the second SAW delay line, c) the power splitting device.

In further exemplary embodiments, it is provided that an amount of a difference between the first delay time and the second delay time is between, e.g., about 1 ns (nanosecond) and, e.g., about 1000 ns, for example between 10 ns and 200 ns, for example 100 ns.

In further exemplary embodiments, it is provided that the first delay time and/or the second delay time is between, e.g., about 0.5 μs (microseconds) and, e.g., about 10 μs, for example between 1 μs and 3 μs, for example 2 μs.

Further exemplary embodiments relate to a measuring system comprising at least one apparatus according to the embodiments and at least one signal source, for example a resonator, adapted to provide the input signal, wherein, for example, the at least one resonator is implemented as a surface acoustic wave resonator.

In further exemplary embodiments, instead of the resonator, for example, a different type of signal source may be used for the measuring system whose signal frequency depends on a quantity to be determined.

In further exemplary embodiments, it is provided that the measuring system is adapted to measure at least one of the following quantities: a) mechanical stresses, for example characterizable and/or associable with bending and/or compression and/or strain and/or torsion, b) torque, c) force, for example as a force sensor and/or force transducer and/or load cell and/or force plate, d) temperature, e) pressure, f) vibration, g) shock, h) resonances, i) shear forces, j) transverse forces, k) elasticity, l) deformation, m) contraction.

In further exemplary embodiments, it is provided that the measuring system comprises at least one signal generator adapted to provide a signal, for example an excitation signal for a or the resonator and/or a reference signal, for example for the six-port circuit.

In further exemplary embodiments, it is provided that the measuring system comprises a coupling device adapted to output an or the excitation signal to at least one resonator and to receive an output signal of the at least one resonator and to output it to at least one input of the six-port circuit and/or to the delay device.

Further exemplary embodiments relate to a method of operating an apparatus having a six-port circuit, a delay device, and a computing device, comprising: dividing an input signal into a first input signal and a second input signal using the delay device, delaying the first input signal by a first delay time using the delay device, wherein, for example, a first delayed input signal is obtained, delaying the second input signal by a second delay time using the delay device, wherein, for example, a second delayed input signal is obtained, the second delay time being different from the first delay time, outputting the first delayed input signal to a first input of the six-port circuit using the delay device, outputting the second delayed input signal to a second input of the six-port circuit using the delay device, and determining a first quantity characterizing a frequency of the input signal in dependence on at least one output signal of the six-port circuit using the computing device.

In further exemplary embodiments, it is provided that the delay device comprises a first surface acoustic wave, SAW, delay line and a second surface acoustic wave, SAW, delay line, the method comprising: delaying the first input signal by the first delay time using the first surface acoustic wave, SAW, delay line, and delaying the second input signal by the second delay time using the second surface acoustic wave, SAW, delay line.

In further exemplary embodiments, it is provided that the method comprises at least one of the following elements: a) switching on or initializing the apparatus or a measurement system comprising the apparatus, b) determining a main resonance of a resonator, c) performing a power calibration, d) performing a linearization, e) determining the first quantity or frequency of the input signal, and optionally adjusting a frequency of an excitation signal sent to the resonator.

Further exemplary embodiments relate to a use of the apparatus according to the embodiments and/or the measurement system according to the embodiments and/or the method according to the embodiments for at least one of the following elements or in at least one of the following fields: a) determining a first quantity characterizing a frequency of the input signal, b) measuring mechanical stresses, for example characterizable or associable with bending and/or compression and/or strain and/or torsion, c) measuring a torque, d) measuring a force, e) measuring a temperature, f) measuring a pressure, g) measuring vibration or vibrations, h) measuring shock, i) measuring resonances, j) automotive, e.g. gearboxes, power take-off shafts, axles, steering columns, load-bearing body components, k) e-bikes or pedelecs, l) working machines, for example mobile working machines, for example gearboxes, power take-off shafts, axles, steering columns, load-bearing body components, dampers, shock absorbers, m) electric drives, n) structures or buildings, for example, regarding statics, structural components, bridge monitoring, wind load, earthquake monitoring, detection of, for example, geological changes, snow load, load, building monitoring, o) power generation, for example, power plant applications, wind turbines, rotor blade monitoring, pitch adjustment, hydropower, p) weight detection, for example, scales, industrial weighing, overload protection, q) temperature measurement and/or monitoring, for example, ovens, cooking, meat preparation and/or processing, r) elevators, for example, freight/passenger elevators, s) industrial applications in mechanical engineering, for example, measurement technology for test stands, t) monitoring, for example, control and/or regulation of turbines, pumps, presses, punches, forming, u) medical technology, for example, exoskeletons, prostheses, operating tables, beds, v) aerospace, for example landing gear load, wing monitoring, rudder monitoring, w) shipping, for example marine applications, x) railroad applications, for example track construction, drive technology, train load, y) implementation of functional safety, z) white goods, washing machine, drum monitoring, dryer, A) fluid technology, valves, flaps, pipes, B) quality assurance, for example process monitoring, C) determination and/or evaluation of chemical compositions of fluids, for example liquids and/or gases.

Further features, possible applications and advantages of the invention are apparent from the following description of embodiments of the invention shown in the figures of the drawing. In this context, all the features described or illustrated constitute the subject-matter of the invention, either individually or in any combination, irrespective of their combination in the patent claims or their correlation, and irrespective of their formulation or representation in the description or in the figures.

### BRIEF DESCRIPTION OF THE DRAWINGS

Further features, aspects and advantages of the embodiments are given in the following detailed description with reference to the drawings in which:

FIG. 1 schematically shows a simplified block diagram according to exemplary embodiments,

FIG. 2 schematically shows a simplified flow diagram according to further exemplary embodiments,

FIG. 3A schematically shows a simplified block diagram according to further exemplary embodiments,

FIG. 3B schematically shows a simplified block diagram according to further exemplary embodiments,

FIG. 4 schematically shows a simplified block diagram according to further exemplary embodiments,

FIG. 5 schematically shows a simplified block diagram according to further exemplary embodiments,

FIG. 6 schematically shows a simplified block diagram according to further exemplary embodiments,

FIG. 7 schematically shows a simplified flow diagram according to further exemplary embodiments, and

FIG. 8 schematically shows aspects of uses according to further exemplary embodiments.

### DETAILED DESCRIPTION

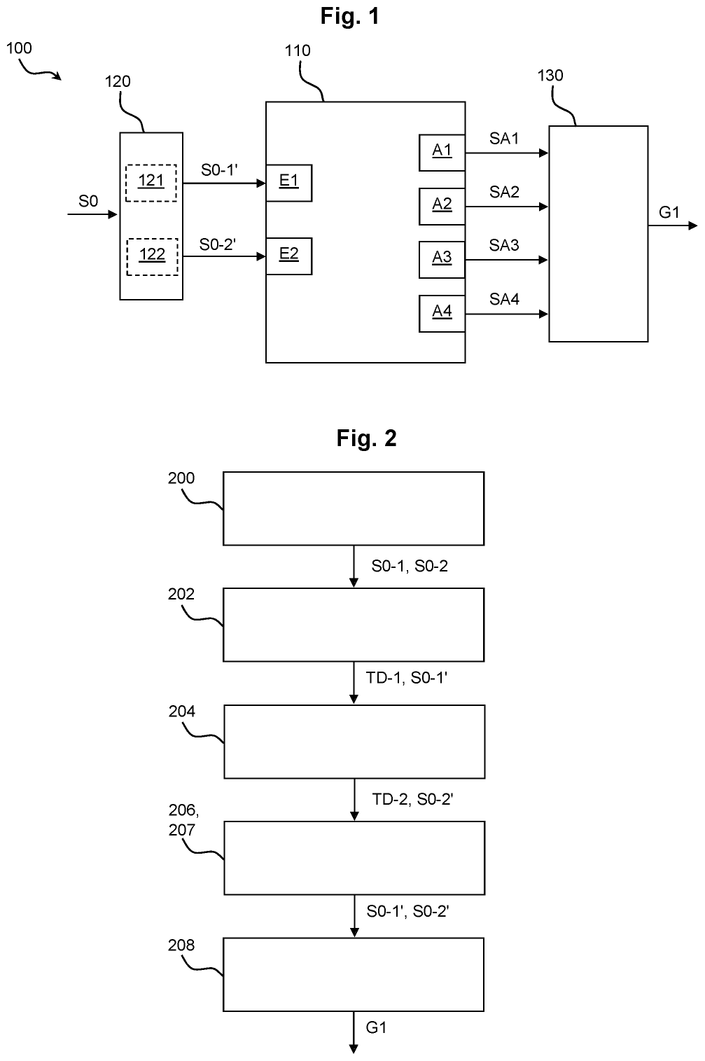

Exemplary embodiments, cf. FIGS. 1 and 2, relate to an apparatus 100 comprising a six-port circuit 110, a delay device 120, and a computing device 130, wherein delay device 120 is adapted to divide 200 an input signal S0 into a first input signal S0-1 and a second input signal S0-2 (FIG. 2), to delay 202 first input signal S0-1 by a first delay time TD-1, wherein, for example, a first delayed input signal S0-1′ is obtained, to delay 204 second input signal S0-2 by a second delay time TD-2, wherein, for example, a second delayed input signal S0-2′ is obtained, the second delay time TD-2 being different from the first delay time TD-1, wherein delay device 120 is adapted to output 206 first delayed input signal S0-1′ to a first input E1 (FIG. 1) of six-port circuit 110 and to output 207 second delayed input signal S0-2′ to a second input E2 of six-port circuit 110, wherein computing device 130 is adapted to determine 208 a first quantity G1 characterizing a frequency of input signal S0 in dependence on at least one output signal SA1, SA2, SA3, SA4 of six-port circuit 110.

In further exemplary embodiments, second delayed input signal S0-2′ has a phase shift d_phi relative to first delayed input signal S0-1′, for example, due to the different delay times TD-1, TD-2. In further exemplary embodiments, the phase shift d_phi depends on the frequency of input signal S0 according to the following equation: d_phi=2*Pi*f*t_dl, wherein “*” is the multiplication operator, Pi is the circular number (3.141 . . . ), f is the frequency of input signal S0, and t_dl is a difference in delay times TD-1, TD-2 to which the first and second input signals S0-1, S0-2, respectively, are subjected when passing through delay device 120.

In further exemplary embodiments, six-port circuit 110 is adapted to evaluate the phase shift between the delayed input signals S0-1′, S0-2′ caused by delay device 120. For this purpose, in further exemplary embodiments, six-port circuit 110 may, for example, superimpose the two delayed input signals S0-1′, S0-2′, which it receives at its inputs E1, E2, on one another at four different phase shifts of, for example, 0°, 90°, 180°, 270°, as a result of which in total four output signals SA1, SA2, SA3, SA4 are obtained, which are output by six-port circuit 110 at the outputs A1, A2, A3, A4 in further exemplary embodiments.

In further exemplary embodiments, six-port circuit 110 is adapted to subject the four output signals SA1, SA2, SA3, SA4 to a frequency down-conversion. In further exemplary embodiments, baseband signals are thereby obtained as the four output signals SA1, SA2, SA3, SA4, respectively.

In further exemplary embodiments, the four output signals SA1, SA2, SA3, SA4, e.g. in the form of the exemplarily mentioned baseband signals, are interpreted as characterizing a complex output vector Z=(SA3−SA4)+j(SA1−SA2), wherein the phase shift d_phi mentioned above can be determined from the phase of the output vector Z in a manner known per se, cf. the following equation: d_phi=tan−1((SA1−SA2)/(SA3−SA4)), where tan−1( ) is the inverse tangent function (arctangent). Provided that the difference t_dl of the delay times TD-1, TD-2 is known, in further exemplary embodiments the frequency of input signal S0, for example representable by the first quantity G1, can be determined as follows:

G1=(d_phi)/(2*Pi*t_dl).

In further exemplary embodiments, an a tan 2 (arctan 2) function defined, e.g., section-wise may be used alternatively or additionally, for example, to obtain a uniqueness range over 2 pi, e.g., according to a tan 2((SA1−SA2),(SA3−SA4)).

In further exemplary embodiments, the above calculations may be performed by computing device 130 using, for example, six-port circuitry 110.

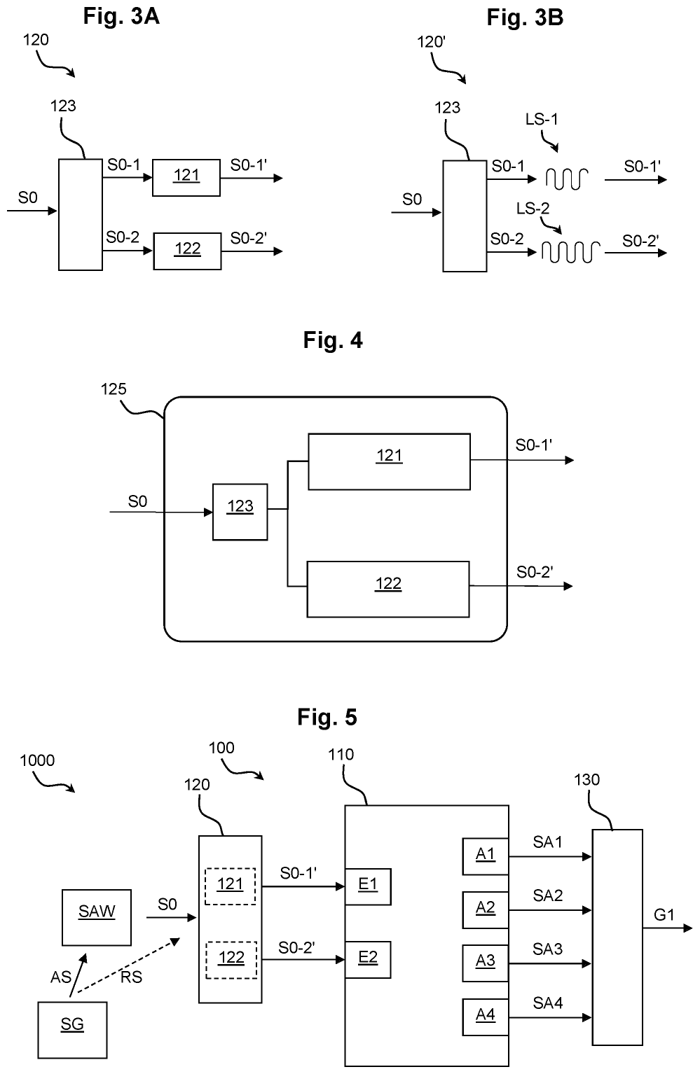

In further exemplary embodiments, FIG. 3A, it is provided that delay device 120 comprises a first surface acoustic wave, SAW, delay line 121 adapted, for example, to delay first input signal S0-1 by first delay time TD-1, wherein delay device 120 comprises a second surface acoustic wave, SAW, delay line 122 adapted, for example, to delay second input signal S0-2 by second delay time TD-2, leading to the two delayed input signals S0-1′, S0-2′, for example.

In further exemplary embodiments, delay device 120 is provided with a power splitting device 123 adapted to split input signal S0 into first input signal S0-1 and second input signal S0-2, e.g., each having equal power (e.g., division factor 0.5).

In further exemplary embodiments, it is provided that first SAW delay line 121 and/or second SAW delay line 122 are each implemented as a discrete SAW delay line. This entails a high degree of flexibility, e.g. with regard to the selection or combination of the delay times TD-1, TD-2.

In further exemplary embodiments, it is provided that first SAW delay line 121 and second SAW delay line 122 are each implemented as a separate SAW delay line component, which, for example, provides physical separation of the two delay lines from each other and thus better decoupling, for example, when both delay lines are not implemented as a single component or are arranged on the same substrate.

FIG. 3B shows a configuration of a delay device 120′ similar to the configuration according to FIG. 3A according to further exemplary embodiments, in which the signal delays are implemented by means of two conductor structures LS-1, LS-2 instead of the SAW delay lines according to FIG. 3A, each of which is symbolized in the present example as rounded meander-shaped lines.

In further exemplary embodiments (not shown), it is also conceivable that delay device 120 comprises signal delay effecting elements of different types, e.g., an SAW delay line for realizing the first delay time and, e.g., a conductor structure for realizing the second delay time.

In further exemplary embodiments, FIG. 4, it is provided that delay device 120 comprises a circuit board 125, wherein at least one of the following elements is arranged on circuit board 125: a) first SAW delay line 121, b) second SAW delay line 122, c) power splitting device 123, d) first conductor structure LS-1, e) second conductor structure LS-2.

In further exemplary embodiments, an amount of a difference between first delay time TD-1 and second delay time TD-2 is between, e.g., about 1 ns(nanosecond) and, e.g., about 1000 ns, for example between 10 ns and 200 ns, for example 100 ns.

In further exemplary embodiments, it is provided that first delay time TD-1 and/or second delay time TD-2 is between, e.g., about 1 μs (microsecond) and, e.g., about 10 μs, for example between 1 μs and 3 μs, for example 2 μs.

In further exemplary embodiments, first delay time TD-1 is 2.0 μs and second delay time TD-2 is 2.1 μs.

Further exemplary embodiments, FIG. 5, relate to a measuring system 1000 comprising at least one apparatus 100 according to the embodiments and at least one resonator SAW adapted to provide input signal S0, wherein, for example, the at least one resonator SAW is implemented as a surface acoustic wave resonator.

In further exemplary embodiments, it is provided that measuring system 1000 is configured to measure at least one of the following quantities: a) mechanical stresses, for example characterizable and/or associable with bending and/or compression and/or strain and/or torsion, b) torque, c) force, for example as a force sensor and/or force transducer and/or load cell and/or force plate, d) temperature, e) pressure, f) vibration, g) shock, h) resonances, i) shear forces, j) transverse forces, k) elasticity, l) deformation, m) contraction, and/or a chemical composition.

In further exemplary embodiments, it is provided that measuring system 1000 comprises at least one signal generator SG adapted to provide a signal, for example an excitation signal AS for resonator SAW and/or a reference signal RS, for example for the six-port circuit.

In further exemplary embodiments, resonator SAW may be excited to oscillate, for example, by application of excitation signal AS. For example, resonator SAW can output input signal S0 for apparatus 100 as a “response” or reaction to the application of excitation signal AS.

In further exemplary embodiments, the frequency of input signal S0 corresponds to a (e.g., instantaneous) resonance frequency of resonator SAW, which, in further exemplary embodiments, may depend on, e.g., among other things, the temperature and/or the pressure and/or the strain and/or other physical quantities and/or environmental influences to which resonator SAW is exposed. A change in the temperature and/or the pressure and/or the strain of the resonator and/or one of the other physical quantities and/or environmental influences then leads, for example, to a change in the resonant frequency of resonator SAW, which can be determined by six-port circuit 110 in further exemplary embodiments.

In this way, the six-port technology can be used, for example, to determine a temperature or a pressure or a (mechanical) strain or other quantities or environmental influences. Advantageously, it can be used, for example, to determine a mechanical stress on a machine element, such as torsion of a shaft.

In further exemplary embodiments, it is provided that signal generator SG is adapted to temporarily provide reference signal RS, e.g. for delay device 120, and/or excitation signal AS for resonator SAW. The excitation signal AS is used to charge resonator SAW with energy, for example. This energy can then be released by resonator SAW, namely via response signal AS at the resonance frequency. In further exemplary embodiments, the frequency of excitation signal AS is at least approximately in the range of the resonant frequency of resonator SAW in order to sufficiently excite the same.

In further exemplary embodiments, signal generator SG may output reference signal RS directly to delay device 120. Since the frequency of reference signal RS is generally known, this can be used to linearize, for example, at least one component 110, 120 or apparatus 100.

In further exemplary embodiments, signal generator SG comprises, for example, an oscillator, in particular a controllable oscillator. For example, according to one embodiment, signal generator SG may comprise a voltage controlled oscillator (VCO). Control of the oscillator may be performed, for example, by computing device 130 of measuring system 1000.

In further exemplary embodiments, signal generator SG includes a frequency synthesizer in which a phase locked loop (PLL) is associated with the oscillator, thereby enabling a particularly frequency-stable signal to be generated in a manner known per se, for example for use as reference signal RS and/or excitation signal AS. In further exemplary embodiments, signal generator SG is configured for direct digital synthesis (DDS) of, for example, reference signal RS and/or excitation signal AS.

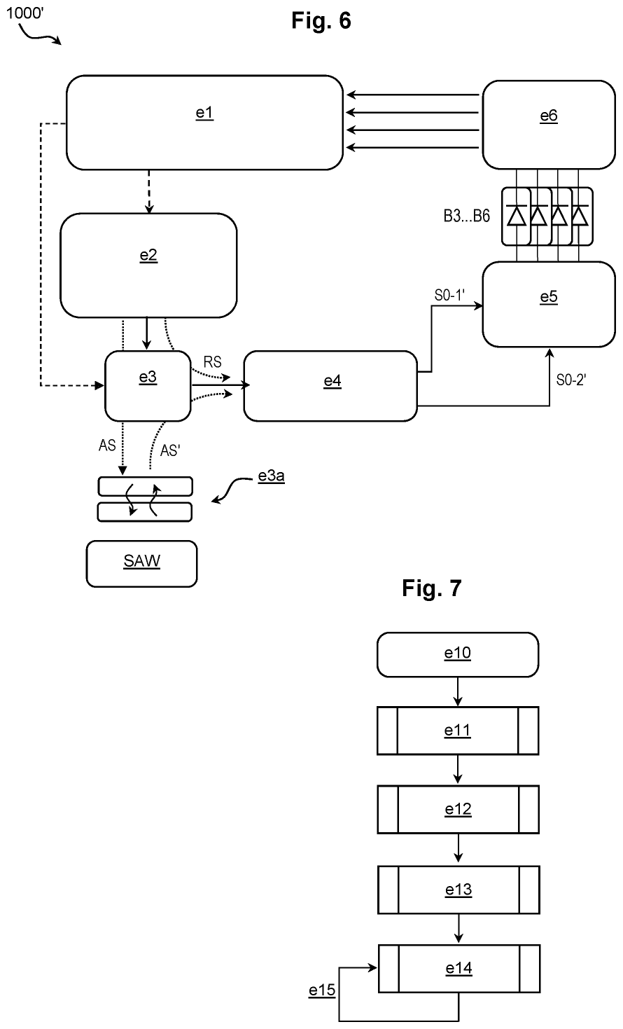

FIG. 6 schematically shows a simplified block diagram of a measuring system 1000′ according to further exemplary embodiments. Block e1 symbolizes a computing device implemented, for example, as a microcontroller, block e2 symbolizes a frequency synthesizer for at least temporarily providing a signal, for example, an excitation signal AS for resonator SAW and/or a reference signal RS for delay device e4.

Block e3 symbolizes a 3-port switch which, in further exemplary embodiments, is adapted to feed the signal generated by frequency synthesizer e2 at least temporarily to a coupling device e3a which is adapted to supply the signal generated by frequency synthesizer e2 as an excitation signal AS to resonator SAW. The 3-port switch e3 is further adapted to receive at least temporarily an output signal AS′ of resonator SAW and to output the same to delay device e4.

In further exemplary embodiments, 3-port switch e3 is adapted to output, at least temporarily, the signal generated by frequency synthesizer e2 as reference signal RS directly (i.e., not via resonator SAW, for example) to delay device e4, which in further exemplary embodiments may be used, for example, for linearization of at least one of the components e4, e5.

Block e5 symbolizes the six-port circuit (cf. also reference sign 110 according to FIG. 1), block e6 symbolizes a processing device which can, for example, perform amplification and/or filtering of the output signals of six-port circuit e5. The diode symbols B3 . . . B6 between blocks e5, e6 symbolize an optional frequency down-conversion of the output signals of six-port circuit e5, e.g. into a baseband position, which enables a particularly simple, cost-effective and efficient further processing, e.g. by block e6, or evaluation by computing device e1.

In further exemplary embodiments, the evaluation by computing device e1 may, for example, comprise a transformation of the output signals of block e6, which are available, for example, as analog (e.g., continuous-value and, e.g., continuous-time) baseband signals, into digital signals (e.g., discrete-value and discrete-time), as well as, for example, a determination of first quantity G1 by way of digital signal processing or calculation by microcontroller e1.

In further exemplary embodiments, microcontroller e1 may operate, for example, as an interface between a host (not shown), e.g., an industrial computer, and measuring system 1000′. In further exemplary embodiments, microcontroller e1 receives and processes instructions sent by the host, sends measurement data back to the host, and adjusts active components, for example.

In further exemplary embodiments, for example, a serial interface of, for example, the universal serial bus (USB) type or the universal synchronous asynchronous receiver transmitter (USART) interface may be provided at microcontroller e1.

In further exemplary embodiments, microcontroller e1 is used, for example, to control the active components of signal generation (e.g. block e2) and/or 3-port switch e3, and/or to sample the analog output signals of “six-port receiver” e5 (or the signals processed by means of block e6), for example, and thus to digitize them.

Since six-port receiver e5 has four outputs (see elements A1, A2, A3, A4 according to FIG. 1), it is advantageous in further exemplary embodiments to provide simultaneous or quasi-simultaneous sampling, e.g., for high measured value update rates and/or minimal measurement errors, e.g., in the case of rapidly changing measured quantities.

In further exemplary embodiments, four dedicated analog-to-digital converters may be provided, for example, in block e1.

In further exemplary embodiments, a resolution of the analog-to-digital converters is, for example, 12 bits or more, and a sampling rate is, for example, 1 MHz (megahertz) or more.

In further exemplary embodiments, computing device e1 may control an operation of frequency synthesizer e2, e.g., via a serial interface, e.g., to transmit instructions for setting a desired frequency for the signal(s) AS, RS.

In further exemplary embodiments, frequency synthesizer e2 is adapted to accurately adjust a frequency of signal AS, RS generated by it in the kilohertz range, for example to an accuracy of less than 100 kHz, for example to an accuracy of less than 10 kHz, and to ensure, for example, the fastest possible settling.

In further exemplary embodiments, frequency synthesizer e2 is adapted to perform direct digital synthesis (DDS) to generate the signal(s) AS, RS.

In further exemplary embodiments, signal AS, RS generated by frequency synthesizer e2 and/or signal AS′ transmitted by resonator SAW is appropriately redirected by 3-port switch e3, which in further exemplary embodiments is controlled, for example, by computing device e1. Consequently, in further exemplary embodiments, there are, for example, three “switch positions”. In a first position of 3-port switch e3, for example, the signal from synthesizer e2 can be forwarded to the six-port circuit or delay device e4, which in further exemplary embodiments can be used, for example, for linearization. With a second switch position, in further exemplary embodiments, excitation of resonator SAW is achieved, wherein the signal generated by block e2 is sent to resonator SAW as an excitation signal AS. In further exemplary embodiments, shortly thereafter, the 3-port switch may change to a third switch position to forward response signal AS′ to delay device e4. In further exemplary embodiments, this switching may also be used, for example, to time window the signal that can be supplied to six-port circuit e5.

In further exemplary embodiments, for example, one or more amplifiers, such as low-noise amplifiers (LNAs) (not shown), may be provided, e.g., in a receive path, thereby increasing the signal-to-noise ratio (SNR).

In further exemplary embodiments, coupling device e3a is implemented, for example, as a high-frequency coupler, e.g. for a contactless measurement of physical quantities, e.g. with respect to a rotating component, e.g. a shaft. In further exemplary embodiments, coupling device e3a enables contactless transmission of the signals AS, AS′, which in further exemplary embodiments are, for example, high-frequency signals in the range of, for example, 2 GHz, for excitation and measurement, for example, even at comparatively large rotational speeds.

In further exemplary embodiments, coupler e3a may include, for example, a stationary component and a component that rotates with the shaft, for example, and that is non-rotatably connected to the shaft, for example, in further exemplary embodiments.

In further exemplary embodiments, resonator SAW is implemented as a SAW sensor, for example, a resonant SAW sensor, for example, with a resonant frequency greater than 2 GHz, for example between 2 GHz and 3 GHz, for example according to an ISM band.

In further exemplary embodiments, for example, a deformation of the shaft caused by a torque may have an effect on response signal AS′ after excitation of resonator AW with excitation signal AS, for example in the form of a frequency shift of the resonant frequency of resonator SAW. In further exemplary embodiments, the change of the resonant frequency of resonator SAW depends, for example, on the torque change.

Further exemplary embodiments, FIG. 2, relate to a method of operating an apparatus 100 having a six-port circuit 110, a delay device 120, and a computing device 130, comprising: dividing an input signal S0 into a first input signal S0-1 and a second input signal S0-2 using delay device 120, delaying 202 first input signal S0-1 by a first delay time TD-1 using delay device 120, wherein, for example, a first delayed input signal S0-1′ is obtained, delaying 204 (e.g., simultaneously with delaying 202) second input signal S0-2 by a second delay time TD-2 using delay device 120, wherein, for example, a second delayed input signal S0-2′ is obtained, the second delay time TD-2 being different from the first delay time TD-1, outputting 206 first delayed input signal S0-1′ to a first input E1 of six-port circuit 110 using delay device 120, outputting 207 second delayed input signal S0-2′ to a second input E2 of six-port circuit 110 using delay device 120, determining 208 a first quantity G1 characterizing a frequency of input signal S0 in dependence on at least one output signal SA1, SA2, SA3, SA4, for example, in dependence on all four output signals SA1, SA2, SA3, SA4, of six-port circuit 110 using computing device 130.

In further exemplary embodiments, it is provided that delay device 120 comprises a first surface acoustic wave, SAW, delay line 121 (FIG. 3) and a second surface acoustic wave, SAW, delay line 122, the method comprising: delaying 202 first input signal S0-1 by first delay time TD-1 using first surface acoustic wave, SAW, delay line 121, delaying 204 second input signal S0-2 by second delay time TD-2 using second surface acoustic wave, SAW, delay line 122.

In further exemplary embodiments, FIG. 7, it is provided that the method comprises at least one of the following elements: a) switching on e10 or initializing apparatus 100 or a measurement system 1000, 1000′ comprising the apparatus, b) determining e11 a main resonance of a or the resonator SAW, c) performing e12 a power calibration, d) performing e13 a linearization, e) determining e14 the first quantity G1 or the frequency of input signal S0, optionally adjusting a frequency of an excitation signal AS sent to resonator SAW, and, optionally, repeating block e13, cf. arrow e15.

In further exemplary embodiments, determining e11 the main resonance comprises: excitation, e.g. temporally successive excitation, of resonator SAW with excitation signals of different frequencies, determining a power of a respective response signal for the different frequencies, using as main resonance frequency that frequency of the different frequencies at which the determined power is maximum.

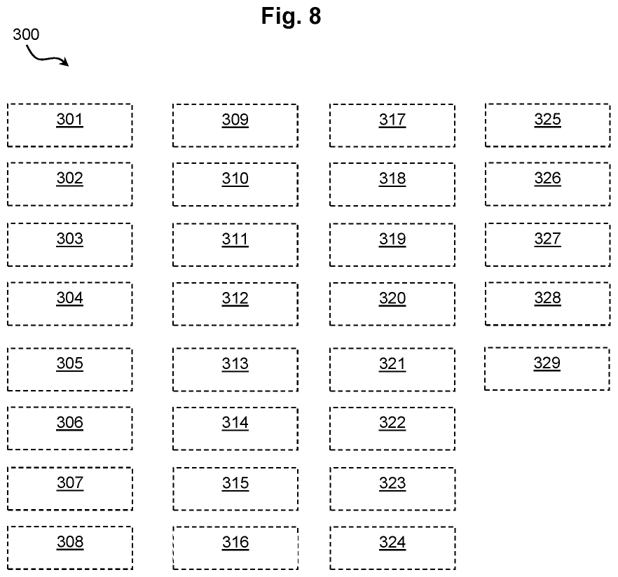

Further exemplary embodiments, FIG. 8, relate to a use 300 of apparatus 100 according to the embodiments and/or measurement system 1000, 1000′ according to the embodiments and/or the method according to the embodiments for at least one of the following elements or in at least one of the following fields: a) determining 301 a first quantity G1 characterizing a frequency of input signal S0, b) measuring 302 mechanical stresses, for example characterizable or associable with bending and/or compression and/or strain and/or torsion, c) measuring 303 a torque, d) measuring 304 a force, e) measuring 305 a temperature, f) measuring 306 a pressure, g) measuring 307 of vibration or vibrations, h) measuring 308 shock, i) measuring 309 resonances, j) automotive 310, e.g. gearboxes, power take-off shafts, axles, steering columns, load-bearing body components, k) e-bikes 311 or pedelecs, l) working machines 312, for example mobile working machines, for example gearboxes, power take-off shafts, axles, steering columns, load-bearing body components, dampers, shock absorbers, m) electric drives 313, n) structures 314 or buildings, for example regarding statics, structural components, bridge monitoring, wind load, earthquake monitoring, detection of, for example, geological changes, snow load, load, building monitoring, o) power generation 315, for example power plant applications, wind turbines, rotor blade monitoring, pitch adjustment, hydropower, p) weight detection 316, for example scales, industrial weighing, overload protection, q) temperature measurement 317 and/or monitoring, for example, ovens, cooking, meat preparation and/or processing, r) elevators 318, for example, freight/passenger elevators, s) industrial applications 319 in mechanical engineering, for example, measurement technology for test stands, t) monitoring 320, for example, control and/or regulation of turbines, pumps, presses, punches, forming, u) medical technology 321, for example, exoskeletons, prostheses, operating tables, beds, v) aerospace 322, for example landing gear load, wing monitoring, rudder monitoring, w) shipping 323, for example marine applications, x) railroad applications 324, for example track construction, drive technology, train load, y) implementation 325 of a functional safety, z) white goods 326, washing machine, drum monitoring, dryer, A) fluid technology 327, valves, flaps, pipes, B) quality assurance 328, for example process monitoring.

1-16. (canceled)

17. An apparatus, comprising:
a six-port circuit;
a delay device, wherein the delay device is adapted to:
divide an input signal (S0) into a first input signal (S0-1) and a second input signal (S0-2);
delay the first input signal (S0-1) by a first delay time (TD-1) to obtain a first delayed input signal (S0-1′);
delay the second input signal (S0-2) by a second delay time (TD-2) to obtain a second delayed input signal (S0-2′), wherein the second delay time (TD-2) is different from the first delay time (TD-1); and
output the first delayed input signal (S0-1′) to a first input (E1) of the six-port circuit and to output the second delayed input signal (S0-2′) to a second input (E2) of the six-port circuit; and
a computing device adapted to determine a first quantity (G1) characterizing a frequency of the input signal (S0) in dependence on at least one output signal of the six-port circuit.

18. The apparatus of claim 17, wherein the delay device (120) comprises one or more of:
a first surface acoustic wave (SAW) delay line adapted to delay (202) the first input signal (S0-1) by the first delay time (TD-1); and
a second SAW delay line adapted to delay the second input signal (S0-2) by the second delay time (TD-2).

19. The apparatus of claim 18, wherein the delay device comprises one or more of:
a first conductor structure (LS-1) adapted to delay the first input signal (S0-1) by the first delay time (TD-1); and
a second conductor structure (LS-2) adapted to delay the second input signal (S0-2) by the second delay time (TD-2).

20. The apparatus of claim 19, wherein the delay device comprises
a power splitting device adapted to split the input signal (S0) into the first input signal (S0-1) and the second input signal (S0-2).

21. The apparatus of claim 20, wherein the first SAW delay line and/or the second SAW delay line are implemented as a discrete SAW delay line.

22. The apparatus of claim 17, wherein the delay device comprises a circuit board, wherein the circuit board includes one or more of the following elements arranged on the circuit board:
a first surface acoustic wave (SAW) delay line adapted to delay the first input signal (S0-1) by the first delay time (TD-1);
a second SAW delay line adapted to delay the second input signal (S0-2) by the second delay time (TD-2);
a power splitting device adapted to split the input signal (S0) into the first input signal (S0-1) and the second input signal (S0-2);
a first conductor structure (LS-1) adapted to delay the first input signal (S0-1) by the first delay time (TD-1); or
a second conductor structure (LS-2) adapted to delay (202) the second input signal (S0-2) by the second delay time (TD-2).

23. The apparatus of claim 17, wherein an amount of a difference between the first delay time (TD-1) and the second delay time (TD-2) is at least one of:
between about 1 nanosecond (ns) and about 1000 ns;
between 10 ns and 200 ns; or
100 ns.

24. The apparatus of claim 17, wherein the first delay time (TD-1) and/or the second delay time (TD-2) is at least one of:
between about 0.5 microseconds (μs) and about 10 μs;
between 1 μs and 3 μs; or
2 μs.

25. The apparatus of claim 17, further comprising:
at least one SAW resonator adapted to provide the input signal (S0).

26. The apparatus of claim 17, wherein the six-point circuit is adapted to superimpose the first delayed input signal (S0-1′) and the second delayed input signal (S0-2′) on one another at four different phase shifts of 0°, 90°, 180°, 270°, to obtain at least four phase shifted output signals (SA1, SA2, SA3, SA4), wherein the at least one output signal of the six-port circuit is one of the four phase shifted output signals (SA1, SA2, SA3, SA4).

27. A measuring system, comprising:
a six-port circuit;
a delay device, wherein the delay device is adapted to:
divide an input signal (S0) into a first input signal (S0-1) and a second input signal (S0-2);
delay the first input signal (S0-1) by a first delay time (TD-1) to obtain a first delayed input signal (S0-1′);
delay the second input signal (S0-2) by a second delay time (TD-2) to obtain a second delayed input signal (S0-2′), wherein the second delay time (TD-2) is different from the first delay time (TD-1); and
output the first delayed input signal (S0-1′) to a first input (E1) of the six-port circuit and to output the second delayed input signal (S0-2′) to a second input (E2) of the six-port circuit;
a computing device adapted to determine a first quantity (G1) characterizing a frequency of the input signal (S0) in dependence on at least one output signal of the six-port circuit; and
at least one signal source adapted to provide the input signal (S0).

28. The measuring system of claim 27, wherein the at least one signal source includes at least one SAW resonator adapted to provide the input signal (S0).

29. The measuring system of claim 27, wherein the measuring system is adapted to measure at least one of the following quantities: a) mechanical stresses, characterizable and/or associable with bending and/or compression and/or strain and/or torsion; b) torque; c) force as a force sensor and/or force transducer and/or load cell and/or force plate; d) temperature; e) pressure; f) vibration; g) shock; h) resonances; i) shear forces; j) transverse forces; k) elasticity; l) deformation; or m) contraction.

30. The measuring system of claim 28, wherein the measuring system comprises:
at least one signal generator (SG) adapted to provide an excitation signal (AS) for the at least one SAW resonator and/or a reference signal (RS) for the six-port circuit.

31. The measuring system of claim 30, wherein the measuring system comprises:
a coupling device adapted to output the excitation signal (AS) to the at least one SAW resonator resonator and to receive an output signal (AS′) of the at least one SAW resonator and to output the output signal (AS′) of the at least one SAW resonator to at least one of the first input and the second input (E1, E2) of the six-port circuit (110) and/or to the delay device (120; e4).

32. The measuring system of claim 27, wherein the six-point circuit is adapted to superimpose the first delayed input signal (S0-1′) and the second delayed input signal (S0-2′) on one another at four different phase shifts of 0°, 90°, 180°, 270°, to obtain at least four phase shifted output signals (SA1, SA2, SA3, SA4), wherein the at least one output signal of the six-port circuit is one of the four phase shifted output signals (SA1, SA2, SA3, SA4).

33. A method of operating an apparatus having a six-port circuit, a delay device, and a computing device, comprising:
dividing an input signal (S0) into a first input signal (S0-1) and a second input signal (S0-2) using the delay device;
delaying the first input signal (S0-1) by a first delay time (TD-1) using the delay device to obtain a first delayed input signal (S0-1′);
delaying the second input signal (S0-2) by a second delay time (TD-2) using the delay device to obtain a second delayed input signal (S0-2′), wherein the second delay time (TD-2) is different from the first delay time (TD-1);
outputting the first delayed input signal (S0-1′) to a first input (E1) of the six-port circuit using the delay device;
outputting the second delayed input signal (S0-2′) to a second input (E2) of the six-port circuit using the delay device;
determining a first quantity (G1) characterizing a frequency of the input signal (S0) in dependence on at least one output signal of the six-port circuit using the computing device.

34. The method of claim 33, wherein the delay device includes a first SAW delay line and a second SAW delay line, the method comprising:
delaying the first input signal (S0-1) by the first delay time (TD-1) using the first SAW delay line; and
delaying the second input signal (S0-2) by the second delay time (TD-2) using the second SAW delay line.

35. The method of claim 34, further comprising at least one of the following:
a) switching on or initializing of the apparatus;
b) switching on or initializing of a measurement system comprising the apparatus;
c) determining a main resonance of a resonator,
d) performing a power calibration,
e) performing a linearization,
f) determining the first quantity or the frequency of the input signal (S0), optionally adjusting a frequency of an excitation signal (AS) sent to the resonator.

36. The method of claim 33, further comprising:
using the apparatus for at least one of the following elements or in at least one of the following fields: a) determining a first quantity characterizing a frequency of the input signal (S0); b) measuring mechanical stresses, for example characterizable or associable with bending and/or compression and/or strain and/or torsion; c) measuring a torque; d) measuring a force; e) measuring a temperature; f) measuring a pressure; g) measuring vibration or vibrations; h) measuring shock; i) measuring resonances; j) using in a vehicle; k) using in an e-bike or pedelec electric cycle; l) using in a working machine and/or using in a gearbox, power take-off shaft, axle, steering column, load-bearing body component, damper, shock absorber; m) using in an electric drive; n) using in a structure or building and/or using for statics, structural components, bridge monitoring, wind load, earthquake monitoring, detection of geological changes, snow load, load, building monitoring; o) using in power generation for power plant applications, wind turbines, rotor blade monitoring, pitch adjustment, hydropower; p) using in weight detection and/or using for scales, industrial weighing, overload protection; q) using in temperature measurement and/or temperature monitoring and/or using for ovens, cooking, food preparation and/or processing; r) using in elevators or freight/passenger elevators; s) using in industrial applications or using in mechanical engineering or using for measurement technology for test stands; t) using for monitoring, control and/or regulation of turbines, pumps, presses, punches, forming; u) using in medical devices and/or exoskeletons, prostheses, operating tables, beds; v) using in aerospace devices and/or using for landing gear load, wing monitoring, rudder monitoring; w) using for shipping or marine applications; x) using for railroad applications and/or for track construction, drive technology, train load; y) using for implementation of safety device; z) using for cleaning devices and/or washing machine, drum monitoring, dryer; aa) using for fluid technology and/or using for valves, flaps, pipes; bb) using for quality assurance and/or for process monitoring; cc) using for determination and/or evaluation of chemical compositions of fluids, including liquids and/or gases.
